(19) United States
(12) Patent Application Publication
(10) Pub. No.: US 2025/0253107 A1
(43) Pub. Date: Aug. 7, 2025

(54) Enhanced tactile feedback mechanism for a keyboard for stenographic input

(71) Applicant: Peter Changhee Park, VISALIA, CA (US)

(72) Inventor: Peter Changhee Park, VISALIA, CA (US)

(21) Appl. No.: 18/434,797

(22) Filed: Feb. 6, 2024

(51) Int. Cl. H01H 13/85; G06F 3/01; G06F 3/02; G06F 3/023; H01H 13/83; H03K 17/96

(52) U.S. Cl. CPC H01H 13/85; G06F 3/016; G06F 3/0219; G06F 3/0231; H01H 13/83; H03K 17/9622

(57) ABSTRACT

The invention relates to an improved touch-sensitive keyboard designed for stenography, which incorporates an enhanced tactile feedback mechanism. This is achieved through the introduction of physical delineations in the form of holes, cuts, or engravings between touch-sensitive key regions on the surface of the keyboard for stenographic input. These physical features allow users to detect the boundaries of individual keys or groups of keys, enabling the precise execution of chording techniques necessary for efficient stenography. The invention aims to replicate the tactile responsiveness of mechanical stenography machines within a modern touch-sensitive format, enhancing user accuracy and speed.

### FIELD OF THE INVENTION

The present invention pertains to the field of input devices for electronic devices, specifically to touch-sensitive keyboards optimized for stenography applications. Stenography is a tool used by court reporters and captioners all over the United States. Stenography enables its users to type at speeds faster than human speech, allowing real-time transcribing and captioning. Traditional stenography machines are expensive due to having numerous mechanical moving parts. A touch-sensitive stenographic input system reduces the cost and makes the skill of stenography accessible to more people.

### BACKGROUND OF THE INVENTION

Stenography is a method of human input requiring the simultaneous pressing of multiple keys, also known as chords, for efficient text entry.

A keyboard for stenographic input is a device intended for human text entry through a chording technique. The present invention involves tactile feedback elements incorporated into a keyboard for stenographic input that comprises a flat surface with touch-sensitive key regions capable of detecting capacitive touch inputs. The layout configuration of the keys is customized for stenography, with keys arranged in a manner conducive to common chording patterns used in stenographic input. Stenographic input requires the user to press multiple keys simultaneously, oftentimes multiple keys with one finger. The keyboard detects touch inputs and sends touch information to the host computer.

A keyboard for stenographic input has a radically different layout and typing system than traditional typing methods such as Qwerty, Colemak, or Dvorak. Instead of pressing one letter at a time to spell out the words, stenography requires combinations of keys to be pressed simultaneously to form entire words in one stroke. When a user presses a combination of letters on a stenographic layout, the resulting combination usually does not spell the word correctly, but rather represents a short-hand, phonetic representation of a word that will be translated by an on-board translation system, or a software program on the host computer such as Plover. For example, if a user presses the letters: KAOEBD on a keyboard for stenographic input, the resulting translation could be “keyboard”. Thus, on a stenographic keyboard, the input is translated into a different output via a translation system.

Stenographic input has traditionally relied on mechanical keyboards with physical keys. The transition to touch-sensitive devices has presented challenges in maintaining high input accuracy due to the lack of tactile feedback. Stenographic input requires one finger to press two or more keys simultaneously. A traditional touch-sensitive surface is flat and does not allow the finger of a user to differentiate between keys when pressed simultaneously. The lack of tactile sensation on a touch-sensitive surface is commonly demonstrated on smartphone keyboards. A traditional touch-sensitive surface does not address the need for precise finger placement and feedback. Thus, there exists a need for a touch-sensitive keyboard design that incorporates an intuitive and physical form of tactile feedback and key differentiation.

### SUMMARY OF THE INVENTION

The invention provides a touch-sensitive keyboard device, specifically designed for stenographic input, that includes an arrangement of tactile feedback elements. The keyboard for stenographic input utilizes a series of tactile feedback elements, otherwise known as holes, cuts, or engravings, strategically placed between keys or groups of keys. These tactile feedback elements are designed to be detected by the user's fingers when two or more keys are pressed simultaneously with a single finger, allowing for the accurate identification of key boundaries and the execution of chording actions without the need for visual cues. This design significantly improves the usability and efficiency of touch-sensitive keyboards for stenographic purposes.

### BRIEF DESCRIPTION OF DRAWINGS

FIG. 1 is an exemplary touch-sensitive keyboard for stenographic input containing numerous tactile feedback elements positioned between keys or groups of keys.

FIG. 2 illustrates a finger hovering over a cross-section of the keyboard for stenographic input. The finger is poised to activate a pair of touch-sensitive key regions, separated by a tactile feedback element.

FIG. 3 illustrates the finger depressing the pair of touch-sensitive key regions, with the tactile feedback elements enhancing the user's ability to execute precise stenographic chords.

### DETAILED DESCRIPTION OF THE INVENTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

Tactile Feedback Elements are incorporated between designated keys or groups of keys on the surface of a keyboard for stenographic input. The invention incorporates tactile feedback elements in the form of holes, cuts, or engravings. These elements are of sufficient depth and width to be discernible by touch when multiple keys are pressed by a single finger. Upon touching the tactile feedback element, the user can easily differentiate between individual keys through the space between them, enabling precise chording actions.

The keyboard for stenographic input is operated by the touch of a finger. The keyboard for stenographic input detects when the user touches any combination of keys. A touch-sensitive key region, also referred to as a key, is an individual touch-sensitive surface that is electrically connected to a processing unit. A key can detect changes in capacitance attributable to the nearby presence of a finger. Upon pressing a key, or a combination of keys, the keyboard's processing unit detects that the key or combination of keys has been pressed and communicates the key presses to the host computer.

A keyboard for traditional typing, such as a Qwerty keyboard, will not benefit from the inclusion of tactile feedback elements placed between the keys. Qwerty does not require users to press multiple keys with a single finger. The tactile feedback elements are only detectable when two or more keys are pressed with one finger because the tactile feedback elements are placed in between the keys. Thus, tactile feedback elements only benefit touch capacitive keyboards for stenographic input.

The keyboard for stenographic input has a processing unit that executes a program instruction that detects changes in the capacitance of the touch-sensitive key regions. Each touch-sensitive key region is electrically connected to a general purpose input-output (GPIO) pin of the processing unit. The processing unit's GPIO pins each have the ability to read and write a “high” state and a “low” state, also known as a 1 and 0 state, by detecting or altering the voltage. If a finger touches a key, the key should normally experience an increase in capacitance. This is due to the natural capacitance of the human body. In order to detect this change in capacitance, a key starts at a “low” state. Then the program writes the GPIO pin to put the key into a “high” state for several milliseconds. The program then writes the GPIO pin to put the key into a “low” state, then counts how much time passes until the key reads a “low” state. The time it takes for the key to read a “low” state indicates the capacitance of the key. In other words, the time it takes for the key to return to a “low” state is directly correlated to the capacitance of the key. This process of setting the pin “high” then “low”, then measuring the time delay, is done hundreds of times per second to detect the state of each key at each moment in time.

The sensitivity of a touch-sensitive key region is calibrated at start up or during use. A non-touch state is measured and stored in memory to serve as a benchmark against any changes in capacitance. If capacitance increases relative to the benchmark number above a threshold value, the program registers this change as a touch. The threshold value can be adjusted to customize the sensitivity of the keys.

A light emitting diode is turned on when a touch is registered. The light emitting diode can also flash on or off to indicate various states of the keyboard to communicate information to the user.

The keyboard for stenographic input can be connected to a host computer via a Universal Serial Bus cable or a wireless connection. Wireless connections include Wi-Fi, Bluetooth, and any other contactless method of information transfer.

The surface of the keyboard for stenographic input can comprise multiple touch-sensitive key regions and multiple tactile feedback elements positioned between keys or groups of keys. The surface may also comprise physical buttons or switches. An example of a physical button is a tactile push button that reboots the keyboard.

A keyboard for stenographic input can be constructed as one solid body, or two separate halves, also known as a split keyboard configuration. On a split keyboard, there is a first keyboard segment and a second keyboard segment. A keyboard that is physically split into two halves allows different posture configurations of the left and right hands during stenographic input.

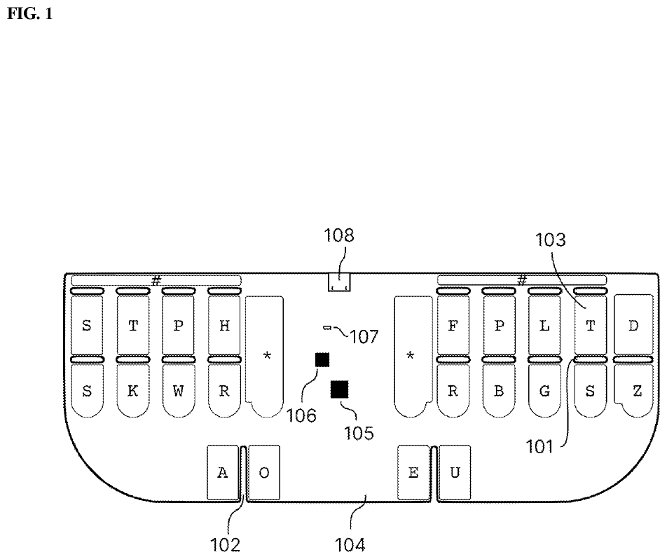

FIG. 1 illustrates an exemplary keyboard for stenographic input. The body (104) comprises touch-sensitive key regions (103) and tactile feedback elements (101 and 102). 101 depicts a tactile feedback element as a hole in the body of the keyboard. 102 depicts a tactile feedback element as a cut in the body of the keyboard. Both 101 and 102 depict a noticeable space between the neighboring touch-sensitive key region, detectable by a human finger. The illustration shows one possible configuration of a processing unit (105), a memory storage unit (106), a light emitting diode (107), and a Universal Serial Bus connection port (108).

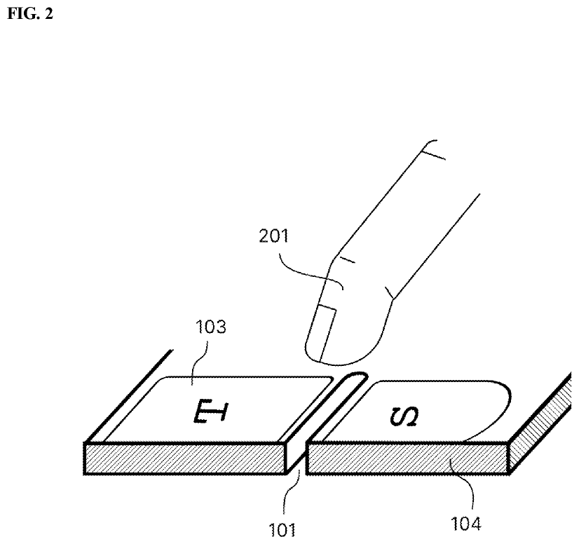

FIG. 2 illustrates a finger (201) positioned above a pair of touch-sensitive key regions (103) on the body of the keyboard (104), indicating the presence of tactile feedback elements (101) between the keys. The finger is not in contact with the keyboard, representing the state prior to key activation. The illustration serves to demonstrate the arrangement of the tactile feedback elements in relation to the keys.

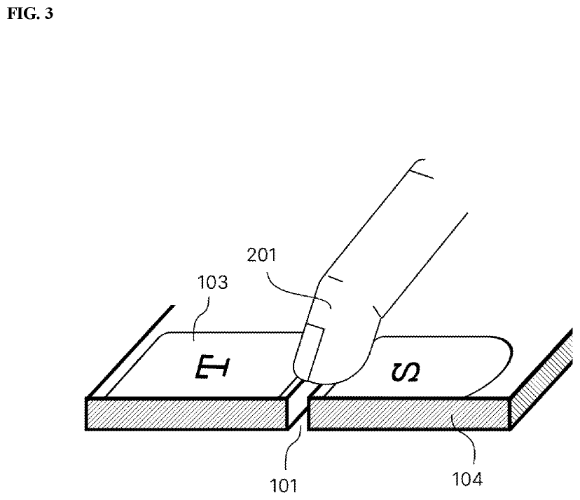

FIG. 3 illustrates the finger (201) pressing down on the touch-sensitive key regions (103) on the body of the keyboard (104), engaging the tactile feedback element (101). The action depicted is of a single finger activating multiple keys simultaneously through a stenographic chording technique. The tactile feedback elements between the keys provide the necessary tactile response, enabling the user to feel the boundaries and press the correct combination of keys without looking.

### LEGEND

101—An exemplary tactile feedback element, depicted as a hole.
102—An exemplary tactile feedback element, depicted as a cut.
103—An exemplary touch-sensitive key region.
104—The body of the keyboard for stenographic input
105—An exemplary processing unit such as a microcontroller.
106—An exemplary memory storage unit.
107—An exemplary light emitting diode.
108—An exemplary Universal Serial Bus connection port.
201—A finger.

1. A keyboard for stenographic input comprising:
touch-sensitive key regions capable of detecting touch inputs;
and tactile feedback elements integrated into a surface of the keyboard for stenographic input, wherein said tactile feedback elements are characterized by holes, cuts, or engravings placed between keys or groups of keys to facilitate tactile feedback and key differentiation by a user when multiple keys are pressed simultaneously with a single finger.

2. The keyboard for stenographic input of claim 1, further comprising one or more light emitting diodes.

3. The keyboard for stenographic input of claim 1, further comprising a Universal Serial Bus connection to a host computer.

4. The keyboard for stenographic input of claim 1, further comprising a wireless connection to a host computer.

5. The keyboard for stenographic input of claim 1, further comprising one or more physical buttons or switches.

6. The keyboard for stenographic input of claim 1, wherein the keyboard comprises a first keyboard segment and a second keyboard segment in a split keyboard configuration, wherein each segment is a physically separate entity.
